(19) United States
(12) Patent Application Publication
(10) Pub. No.: US 2026/0271664 A1
(43) Pub. Date: Sep. 10, 2026

(54) ROBOT ARM WITH VACUUM-COMPATIBLE SEALS AND INTERNAL COOLING FLOW PATHS

(71) Applicant: Lam Research Corporation, Fremont, CA (US)

(72) Inventor: Richard M. Blank, San Jose, CA (US)

(21) Appl. No.: 18/876,567

(22) PCT Filed: Jun. 26, 2023
(86) PCT No.: PCT/US2023/026180

§ 371 Date: Dec. 18, 2024

Related U.S. Application Data
(60) Provisional application No. 63/367,583, filed on Jul. 1, 2022.

(51) Int. Cl. H10P 72/30; B25J 9/16; B25J 19/00; H05K 7/20; H10P 72/00

(52) U.S. Cl. CPC H10P 72/3202; B25J 9/1697; B25J 19/0054; H05K 7/20218; H10P 72/0464; H10P 72/0606

(57) ABSTRACT

This disclosure describes robot arm assemblies for use in vacuum environments. Such robot arm assemblies may feature one or more rotational joints that have ferrofluidic seals or other vacuum-compatible seals. Coolant flow path segments may be provided that pass through one or more of the one or more rotational joints so as to allow coolant to be circulated through one or more cooling features located within the robot arm assembly, thereby allowing components within the robot arm assembly, e.g., motors, ferrofluidic seals, sensors, etc., to be actively cooled.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools typically feature a plurality of semiconductor processing chambers arranged about a vacuum transfer module (VTM). Such VTMs often have one or more wafer-handling robots, each wafer-handling robot having one or more robot arm assemblies that are able to be used to move one or more corresponding end effectors between different locations within or adjacent to the VTM, e.g., to transfer wafers from one location to another. For example, such wafer-handling robots may be configured to move wafers from one processing chamber that is connected with the VTM to another processing chamber that is connected with the VTM, or potentially from a load lock or processing chamber connected with the VTM to a buffer station located within the VTM.

The interiors of VTMs, as implied by the name, may generally be kept under vacuum conditions, i.e., sub-atmospheric pressure, in order to match or at least be close to, the pressures that the processing chambers attached thereto are typically kept at, thereby reducing the pressure differential between the processing chambers and the VTM that must be restored after one of the processing chambers and the VTM are fluidically connected, e.g., by opening a valve or door that fluidically isolates them from each other.

Discussed herein are various improvements to robots that may be used in vacuum environments.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a robot arm base, a robot arm assembly including one or more arm links and a first set of one or more rotational joints, each rotational joint of the first set of one or more rotational joints including a corresponding vacuum-compatible seal, components defining a plurality of coolant flow path segments, and a first set of one or more cooling features, each cooling feature in the first set of one or more cooling features fluidically connected with, and fluidically interposed between, at least two of the coolant flow path segments. A base rotational joint of the one or more rotational joints may rotatably connect a first arm link of the one or more arm links to the robot arm base, and at least two of the coolant flow path segments may extend from the robot arm base, through the base rotational joint, and into at least the first arm link.

In some implementations, the one or more vacuum-compatible seals may include at least a first vacuum-compatible seal, and the one or more cooling features may include one or more vacuum-compatible seal cooling features, the one or more vacuum-compatible seal cooling features including a first vacuum-compatible seal cooling feature that is configured to cool the first vacuum-compatible seal when a coolant is flowed into the first vacuum-compatible seal cooling feature via at least one of the coolant flow path segments and out of the first vacuum-compatible seal cooling feature via at least one other coolant flow path segment of the coolant flow path segments.

In some such implementations, the first vacuum-compatible seal cooling feature may include a passage that extends through at least part of a tubular zone that has a centerline that is coaxial with a rotational axis of the one of the one or more rotational joints that includes the first vacuum-compatible seal, and the tubular zone may encircle one or more surfaces of the first vacuum-compatible seal that face radially inward towards the rotational axis of the one of the one or more rotational joints that includes the first vacuum-compatible seal.

In some implementations, the passage may be bounded, at least in part, by one or more surfaces of the first vacuum-compatible seal that face radially outward from the rotational axis of the one of the one or more rotational joints that includes the first vacuum-compatible seal.

In some implementations, the first vacuum-compatible seal cooling feature may include a passage that extends through at least part of a tubular zone that has a centerline that is coaxial with a rotational axis of the one of the one or more rotational joints that includes the first vacuum-compatible seal, and the tubular zone may be encircled by one or more surfaces of the first vacuum-compatible seal that face radially inward towards the rotational axis of the one of the one or more rotational joints that includes the first vacuum-compatible seal.

In some implementations, the passage may be bounded, at least in part, by the one or more surfaces of the first vacuum-compatible seal that face radially inward towards the rotational axis of the one of the one or more rotational joints that includes the first vacuum-compatible seal.

In some implementations, the passage may have an annular or annular sector shape.

In some implementations, the robot arm assembly may include a first motor, and the one or more cooling features may include one or more motor cooling features, the one or more motor cooling features including a first motor cooling feature that is positioned adjacent to or encircling a portion of the first motor and configured to cool the first motor when a coolant is flowed into the first motor cooling feature via at least one of the coolant flow path segments and out of the first motor cooling feature via at least one other coolant flow path segment of the coolant flow path segments. In some implementations, the one or more cooling features may include one or more arm link cooling features, the one or more arm link cooling features including a first arm link cooling feature that is positioned adjacent to, or within, material forming one of the one or more arm links and configured to cool that arm link when a coolant is flowed into the first arm link cooling feature via at least one of the coolant flow path segments and out of the first arm link cooling feature via at least one other coolant flow path segment of the coolant flow path segments.

In some implementations, the first arm link cooling feature may extend along at least half of the length of the arm link the material of which the first arm link cooling feature is positioned adjacent to or within. In some implementations, the apparatus may further include a first sensor located within one of the one or more arm links, the one or more cooling features may include one or more sensor cooling features, and the one or more sensor cooling features may include a first sensor cooling feature that is positioned adjacent to or encircling a portion of the first sensor and configured to cool the first sensor when a coolant is flowed into the first sensor cooling feature via at least one of the coolant flow path segments and out of the first sensor cooling feature via at least one other coolant flow path segment of the coolant flow path segments.

In some implementations, the first sensor may be an optical sensor.

In some implementations, the first sensor may be an imaging sensor,

In some implementations, the one or more arm links may include a first end effector arm link having a first end effector, and the first sensor may be in the first end effector arm link. In some implementations, the first sensor may be oriented to collect data from a location underneath the first end effector arm link.

In some implementations, the first sensor may be oriented to collect data from a location above the first end effector arm link.

In some implementations, the first end effector arm link may also be the first arm link.

In some implementations, the apparatus may further include a second sensor, the one or more arm links may further include a second end effector arm link having a second end effector, the second sensor may be located within the second end effector arm link, the one or more arm links may further include a forearm link, the first end effector arm link may be rotatably connected with the forearm link by a first rotational joint of the one or more rotational joints, the second end effector arm link may be rotatably connected with the forearm link by a second rotational joint of the one or more rotational joints, and the one or more sensor cooling features may include a second sensor cooling feature that is positioned adjacent to or encircling a portion of the second sensor and configured to cool the second sensor when a coolant is flowed into the second sensor cooling feature via at least one of the coolant flow path segments and then out of the second sensor cooling feature via at least one other coolant flow path segment of the coolant flow path segments.

In some implementations, the first rotational joint may be configured such that the first end effector arm link is rotatable about a first rotational axis relative to the forearm link, the second rotational joint may be configured such that the second end effector arm link is also rotatable about the first rotational axis relative to the forearm link, the first end effector may be positioned at a higher elevation than the second end effector, the first end effector link may include a first body portion and a first shaft portion, the first shaft portion may extend through the second end effector link, the first shaft portion may be supported by the first rotational joint, the first rotational joint may include a first vacuum-compatible seal that seals between the second end effector link and the first portion of the first end effector link, the second sensor and the second sensor cooling feature may both be located within the second arm link at a location that is radially outboard of the first vacuum-compatible seal with respect to the first rotational axis, and the first vacuum-compatible seal may be interposed between the first body portion and a location on the first shaft portion where coolant flow path segments leading to the second sensor cooling feature exit the first portion.

In some implementations, an opening may extend through the first shaft portion across a sector of arc about the first rotational axis, and the coolant flow path segments leading to the second sensor cooling feature may exit the first shaft portion via the opening.

In some such implementations, the sector of arc may extend through at least 90°.

In some implementations, the one or more arm links may include a plurality of arm links.

In some implementations, a second rotational joint may rotatably connect two arm links of the plurality of arm links, at least two of the coolant flow path segments may pass through the base rotational joint, and at least two of the coolant flow path segments may pass through the second rotational joint.

In some implementations, at least some of the coolant flow path segments may be provided, at least in part, by flexible polymeric tubing.

In some implementations, the components defining each flow path segment may include components selected from one or more of: lengths of flexible polymeric tubing, lengths of rigid tubing, flow-splitting devices, pass-through connectors, and fittings.

In some implementations, the apparatus may further include a purge gas bleed feature. The purge gas bleed feature may include one or more purge gas outlets fluidically connected with one or more purge gas plenums and configured to direct purge gas from the one or more purge gas plenums radially outward in proximity to a corresponding one of the one or more rotational joints. Additionally, one or more purge gas lines may be routed from the robot arm base, through the base rotational joint, and into at least the first arm link.

In some implementations, at least one of one or more rotational joints may include a corresponding vacuum-compatible seal that is a ferrofluidic seal.

In some implementations, each rotational joint may include a corresponding vacuum-compatible seal that is a ferrofluidic seal.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a diagram of an example wafer-handling robot that incorporates rotational joints having vacuum-compatible seals and an active cooling system.

FIG. 1A depicts a detail view of a portion of the wafer-handling robot of FIG. 1 marked within boundary box A.

FIG. 1B depicts a detail view of a portion of the wafer-handling robot of FIG. 1 marked within boundary box B.

FIG. 1B′ depicts an alternate configuration that may be implemented in the wafer-handling robot of FIG. 1.

FIG. 1C depicts a detail view of a portion of the wafer-handling robot of FIG. 1 marked within boundary box C.

FIG. 1C′ depicts an alternate configuration that may be implemented in the wafer-handling robot of FIG. 1.

FIG. 2 depicts a diagram of an example ferrofluidic seal.

FIG. 3 depicts a diagram of an example rotational bearing.

FIGS. 4A through 4C depict schematics of different arrangements of coolant flow path segments.

FIG. 5 depicts a diagram of a VTM that has a plurality of processing chambers attached thereto and that contains a wafer-handling robot as disclosed herein.

The above-described Figures are provided to facilitate understanding of the concepts discussed in this disclosure, and are intended to be illustrative of some implementations that fall within the scope of this disclosure, but are not intended to be limiting—implementations consistent with this disclosure and which are not depicted in the Figures are still considered to be within the scope of this disclosure.

### DETAILED DESCRIPTION

As noted earlier, semiconductor processing tools often include a vacuum transfer module (VTM) that may include one or more wafer-handling robots that have robot arm assemblies located within the interior of the VTM. Such robot arm assemblies typically include at least one rotational joint that connects the robot arm assembly to a robot arm base that is fixed with respect to the VTM, e.g., mounted to the underside of the VTM. The robot arm base may, for example, contain one or more motors that may be actuated in order to rotate and/or lift the robot arm assembly relative to the base. At the very least, a wafer handling robot will have at least one rotational joint that allows the robot arm assembly thereof to rotate relative to the robot arm base.

In many instances, the robot arm assemblies that are included in VTMs may include multiple arm links, e.g., rigid links that are connected end-to-end by corresponding rotational joints to allow each link to be rotated relative to the other link or links it is connected with. For example, a robot arm assembly with three links may be able to cause the end-most arm link to rotate about the robot arm base, move to any of a variety of locations around the robot arm base, and/or rotate relative to the other arm links, thereby providing great flexibility with regard to where such a robot arm assembly may transport wafers between. Thus, while some implementations of the concepts discussed herein may feature a robot arm assembly having only one rotational joint and one arm link, it will be understood that other implementations of the concepts discussed herein may feature a robot arm assembly having multiple rotational joints and multiple arm links.

Disclosed herein are new types of robot arms for use in vacuum environments such as a VTM. By equipping each rotational joint in a robot arm assembly with a corresponding vacuum-compatible rotational seal (e.g., a ferrofluidic seal), it is possible to fluidically isolate the interior spaces of the robot arm assembly from such vacuum environments while, at the same time, allowing the interior spaces within the robot arm link(s) to be fluidically connected, e.g., with the robot arm base. By virtue of such fluidic isolation, the interior spaces within the robot arm link(s) may be kept at a higher pressure, e.g., atmospheric pressure, as compared with the vacuum environment surrounding the robot arm assembly. This may, for example, facilitate cooling of various components, e.g., sensors, motors, bearings, etc., that may be located within the robot arm assembly. For example, sensors, motors, and bearings may all generate heat during use, e.g., heat generated due to resistance by electrical components and/or heat generated due to friction or rolling resistance in mechanical components. Such heat may be difficult to dispose of passively, e.g., through thermal conduction through the robot arm segments. Configuring a robot arm assembly to have sealed rotational joints such that the interior of the robot arm assembly can be kept at a higher pressure than the vacuum environment within which the robot arm assembly is used permits, for example, the use of flexible polymeric tubing to be routed through the interior spaces of the robot arm assembly, e.g., through one or more of the one or more rotational joints of the robot arm assembly. Such tubing may be used to define coolant flow path segments that may be used to circulate a coolant through one or more cooling features that may be positioned adjacent to, or located within, components that may require cooling and that are located within the robot arm link or links. The use of such flexible tubing may allow for routing of the flow paths through the rotational joint(s) without needing to resort to complex rotational joints that incorporate a fluid transfer function, such as rotary unions. The use of flexible tubing for routing fluids in a vacuum environment (at least, within vacuum environments with strict atmospheric purity requirements, such as in semiconductor processing systems) is generally avoided since most such tubing is made of materials that would present outgassing issues and/or would have insufficient rigidity to prevent inflation of the tubing when subjected to a vacuum environment while pressurized. Teflon is likely one of the only suitable candidate materials for such use, and even the use of Teflon in such contexts is typically discouraged due to the potential for leaks (either through the material itself or at locations where the tubing connects with a fitting).

Additionally, sealing the interior spaces of the robot arm assembly off from the vacuum environment that surrounds the robot arm assembly allows the use of components within the interior of the robot arm assembly that might otherwise be problematic. For example, polymeric tubing for fluid transport, polymeric sheathing for cables or wiring, adhesives, ball bearings, lubricants, etc. may generate contaminants, e.g., chemical species, dust or particulates, etc., that may, if able to leak into the vacuum environment, may present a serious contamination issue. For example, particulates that may be generated due to friction wear of bearings within the interior of the robot arm assembly may be drawn into the vacuum environment and may come to rest on a wafer being transported through such an environment, thereby contaminating the wafer and potentially reducing process yield. Similarly, gas species that may outgas from polymeric components within the interior of the robot arm assembly may leak out into the vacuum environment and may react with materials located on a wafer being transported through the vacuum environment, thereby affecting wafer uniformity and degrading the wafer yield. By including ferrofluidic seals, or other vacuum-rated rotational interfaces, in such a robot arm assembly, the robot arm assembly may be caused to be sealed off from the vacuum environment such that there is little or no chance of contaminants originating from the interior of the robot arm assembly being able to migrate into the vacuum environment.

Robot arm assemblies such as those described herein may be configured to be able to actively cool components located in any of the arm links of a multi-link robot arm assembly, thereby facilitating the placement of heat-generating or heat-sensitive features in even the end-most arm link of such a robot arm assembly. This may, for example, allow for the placement of equipment, e.g., motors, bearings, seals, and/or sensors in locations within such robot arm assemblies that would otherwise ordinarily be difficult to cool. Additionally, it may often be the case that a wafer handling robot, for example, may be required to retrieve or handle wafers that are at elevated temperatures, e.g., 200° C. or more. Such wafers may radiate heat energy that is absorbed by the end effector(s) of such a robot arm assembly, thereby contributing additional heat energy to components within those portions of the robot arm assembly that are thermally proximate to the end effectors.

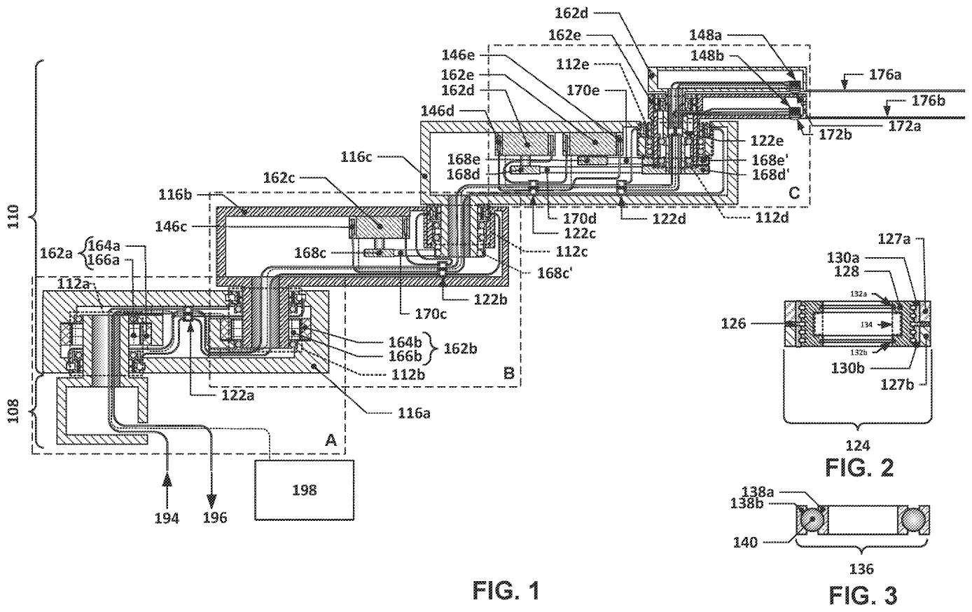

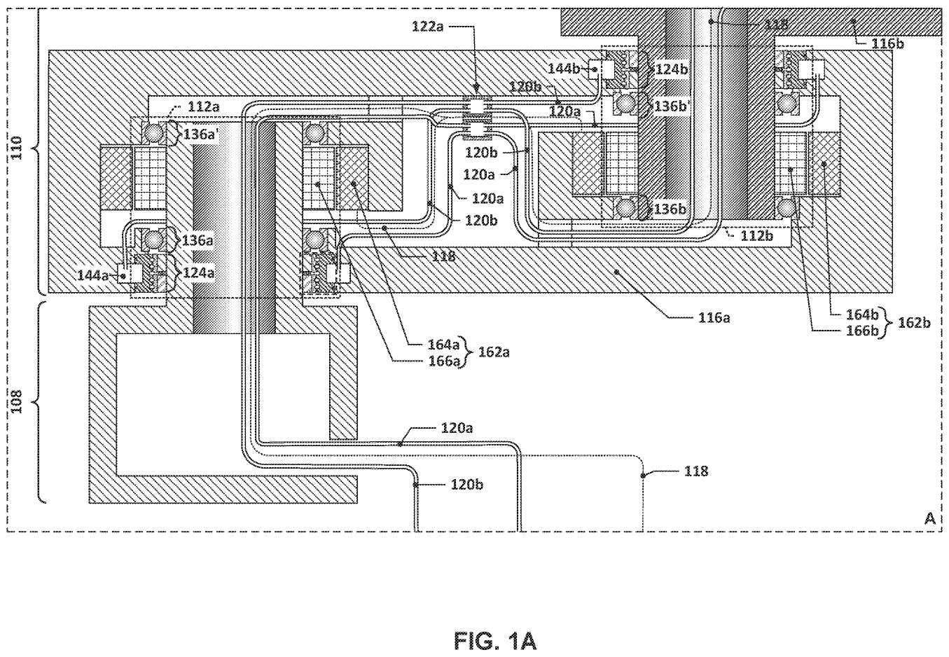

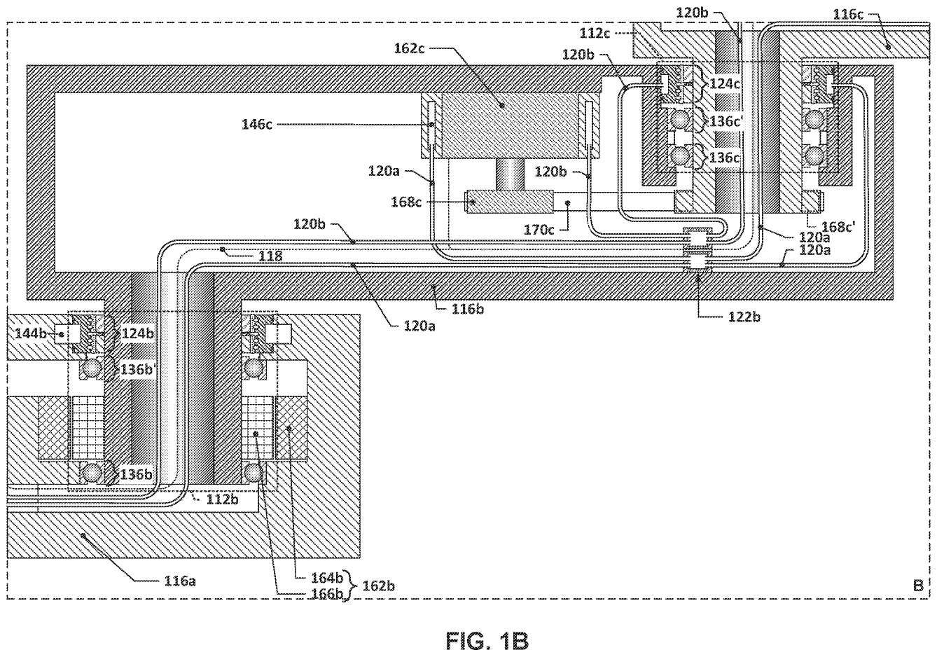

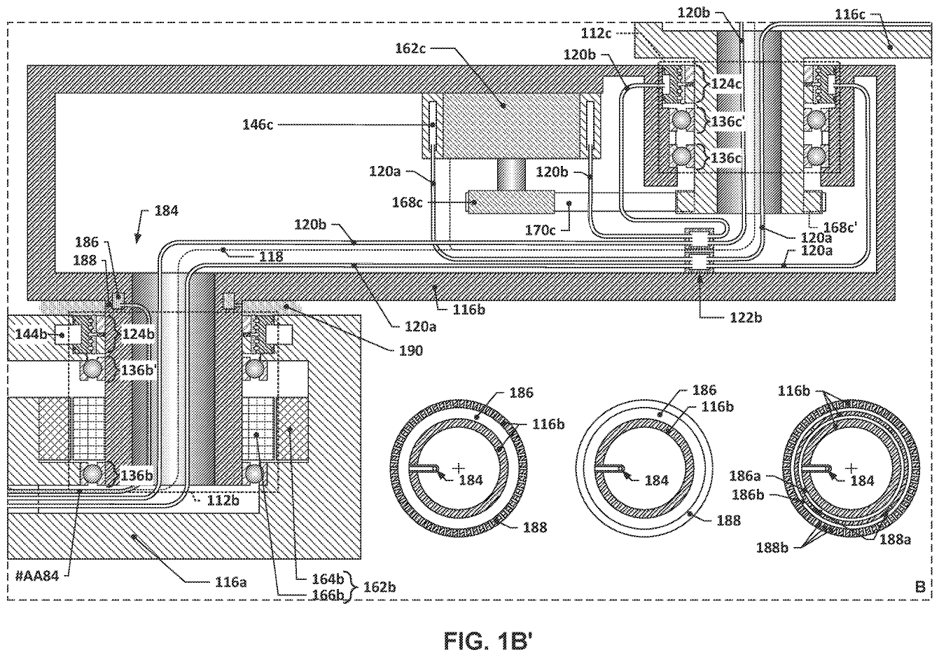

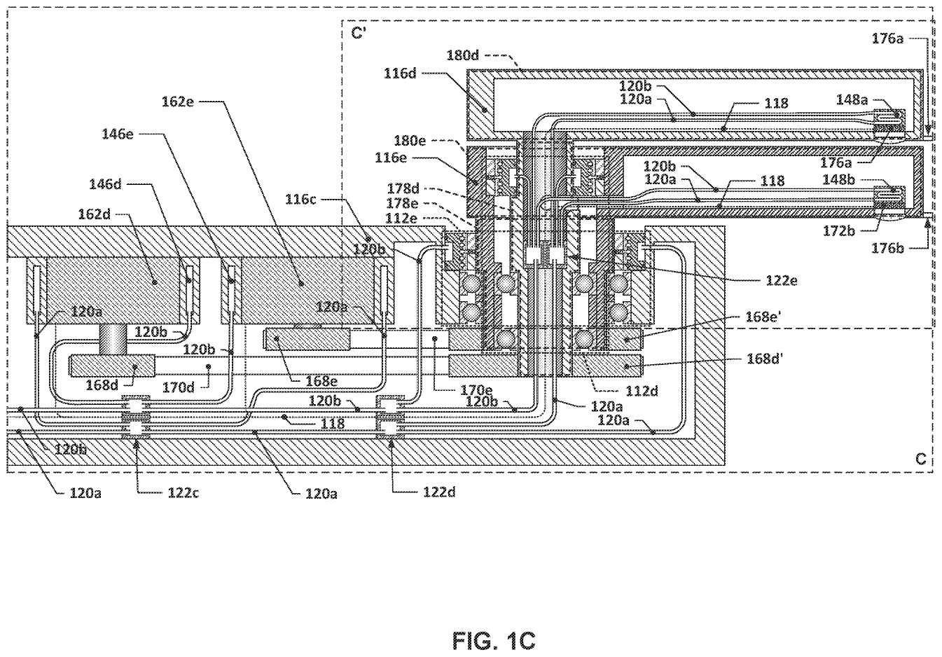

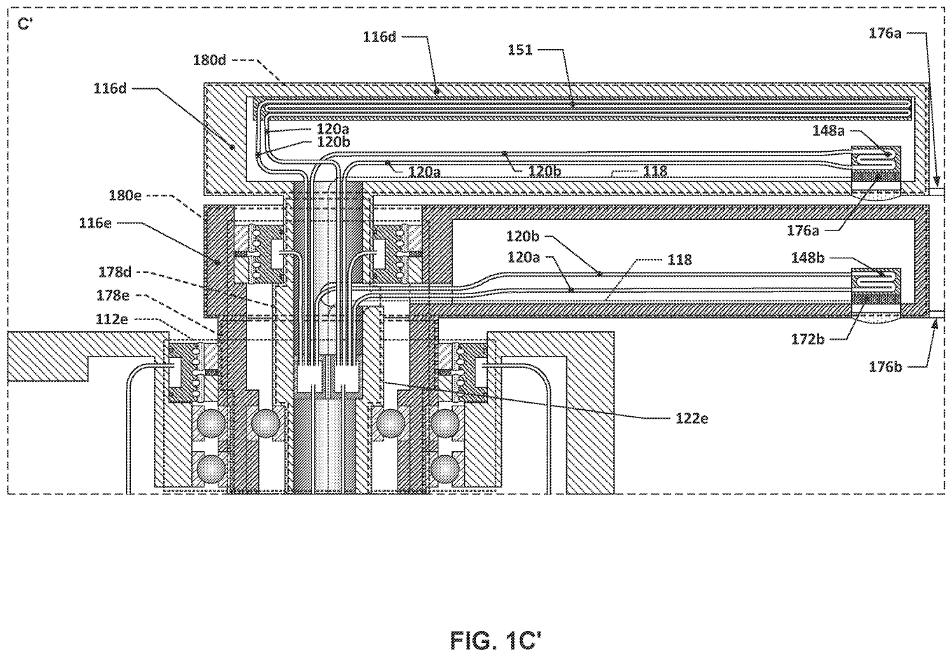

FIG. 1 depicts a diagram of an example wafer-handling robot that incorporates rotational joints having vacuum-compatible seals and an active cooling system such as is referenced above. FIG. 1 includes three dashed-line rectangular boundaries labeled “A,” “B,” and “C” that each correspond with the boundaries of FIGS. 1A, 1B, and 1C, respectively. FIGS. 1A, 1B, and 1C may be understood to represent detail views of the portions of the wafer handling robot of FIG. 1 that are enclosed within each rectangular boundary.

It will be understood that the wafer handling robot of FIG. 1 is provided as an example robot that demonstrates a particular configuration of robot arm assembly, e.g., having multiple arm links and multiple end effectors. However, it will also be understood that the concepts discussed with respect to the wafer handling robot of FIG. 1 may also be implemented in robot arm assemblies having a greater or lesser number of arm links (including only a single arm link) and/or a greater or lesser number of end effectors. Additionally, the example wafer handling robot of FIG. 1 includes three different types of components that are provided with active cooling. It will be understood that other implementations may include only some of such components, or may include components other than those shown which may be cooled in a similar manner.

It will also be understood that multiple instances of several elements or features are depicted in FIG. 1; in some such cases, the different instances of such elements or features may be referred to by the same callout number but with a different lower case suffix, e.g., 100a, 100b, 100c, etc. It will be understood that reference to such elements generally may be made using only the numeric portions of such callouts, e.g., omitting the letter suffix, even though there may not be any specific callout that consists only of the number in question. Moreover, it will be understood that in some cases, the letter suffixes that are used for some element or feature instances may not be sequential, e.g., there may be instances 100c and 100d but no instances 100a or 100b.

In FIG. 1, a cross-section diagram of a wafer handling robot 106 is depicted. The wafer handling robot 106 may include a robot arm base 108 and a robot arm assembly 110 that is supported by the robot arm base 108. The robot arm assembly 110 may include one or more arm links 116 that, in this example, include a first arm link 116a, a second arm link 116b, a third arm link 116c, a fourth arm link 116d, and a fifth arm link 116e. The robot arm assembly 110 may also include a set of one or more rotational joints 112. In this example, the set of rotational joints in the robot arm assembly 110 includes a first rotational joint 112a, a second rotational joint 112b, a third rotational joint 112c, a fourth rotational joint 112d, and a fifth rotational joint 112e. Each of the rotational joints 112 in the set of rotational joints 112 may include one or more rotational bearings 136 and a ferrofluidic seal 124. It will be understood that while the present disclosure uses ferrofluidic seals as the vacuum-compatible seals in the examples below, other types of vacuum-compatible rotational seals may be used as well, and references to “ferrofluidic seal cooling features” may be understood to also be replaceable with references to “vacuum-compatible seal cooling features.” Vacuum-compatible seals, for example, may be understood to provide a seal across a rotational interface that is sufficient to permit a vacuum to be maintained on one side of the seal, e.g., vacuums in the range of 40 mTorr to 550 mTorr or lower, while atmospheric pressure is maintained on the other side of the rotational interface. In some instances, vacuum-compatible seals may include sliding seals, e.g., where there is sliding contact between a compliant seal structure (such as an elastomeric seal) and a sealing surface (such as a shaft). In other instances, vacuum-compatible seals may include non-sliding seals, e.g., where there is no sliding contact between two structures at the seal interface. In such vacuum-compatible seals, for example, the seal element may be provided by a fluid material, such as a ferrofluid, thereby eliminating rubbing between discrete parts at the seal interface and reducing particulate generation.

The rotational bearings 136 may, for example, be ball bearings or other bearings that may allow one arm link 116 to rotate relative to another or to the robot arm base. In this example, the rotational bearings 136 each include an inner race 138a, an outer race 138b, and a plurality of ball bearings 140 interposed therebetween, as shown in the example rotational bearing of FIG. 3.

The ferrofluidic seals 124 are a class of seals that may be used to provide a vacuum-compatible seal across a rotational interface between two components that are configured to rotate relative to one another. A typical ferrofluidic seal, as shown in FIG. 2, may include two generally annular pole pieces 127a and 127b that have coaxial centerlines and are spaced apart from one another along those centerlines. The pole pieces 127 may, for example, be made of a ferrous material, e.g., iron. A circular array of magnets 126 may be interposed between the two pole pieces 127 such that the polarities of the magnets 126 are oriented in the same direction, e.g., the N side of each magnet may be magnetically clamped to the pole piece 127a and the S side of each magnet may be magnetically clamped to the pole piece 127b. In some instances, a single annular magnet 126 may be used in place of the circular array of magnets 126.

A core 128 may be positioned so as to pass through the pole pieces 127. The core 128 may, for example, have a centerline that is coaxial with the centerlines of the pole pieces 127. The core 128 may be supported relative to the pole pieces 127 by one or more rotational bearings such that the core 128 is concentric with the interior surface(s) of the pole pieces 127 and such that a small radial gap exists between the outermost surface of the core 128 and the surfaces of the pole pieces 127 that face radially inward in the regions that axially overlap with the pole pieces 127. The core 128 may include a plurality of circumferential grooves or furrows along portions of its length that axially overlap with the pole pieces 127, thereby causing a plurality of circumferential ridges or corrugations to be proximate to the pole pieces 127. The magnetic field provided by the magnets 126 may generate a somewhat toroidal magnetic flux zone, with flux bands travelling from the magnet(s) 126 into the pole piece 127a and then jumping through the gap between the core 128 and the pole piece 127a. The flux bands then travel along the core 128 and then jump back across the gap into the pole piece 127b before returning to the magnet(s) 126.

The flux strength within the gap will naturally be stronger at the locations where each circumferential “ridge” exists as compared with the circumferential “valleys” in between the circumferential ridges. When ferrofluids 130 are introduced into the gaps between the pole pieces 127 and the core 128, the ferrofluids will naturally congregate in the radial gaps between the circumferential ridges and the pole pieces 127 due to the higher flux in those regions. This creates a series of ferrofluidic barriers that span across the gap, e.g., from the pole pieces 127 to the core 128. Each such barrier may act as a seal such that, in effect, a series of circumferential seals are provided by the ferrofluids 130. When subjected to a vacuum environment, the ferrofluidic seals, in aggregate, may form a leak-proof (or sufficiently leak-proof) interface between the core 128 and the pole pieces 127, thereby allowing the core 128 and the pole pieces 127 to rotate relative to one another while preventing gas from leaking therethrough. Additionally, since the ferrofluids 130 are magnetic, particulate debris that may be generated from the ferrofluids 130 will tend to remain trapped in between the pole pieces 127 and the core 128, thereby reducing or eliminating the potential for particulate contamination within the interior of a VTM from the rotational joints 112.

In some ferrofluidic seals, the core 128 and the pole pieces 127 may be positionally reversed, with the core 128 encircling the pole pieces 127 instead of the pole pieces 127 encircling the core 128.

Additionally, in some ferrofluidic seals, the ferrofluidic seal may include one or more cooling cavities through which a coolant may be flowed in order to cool the ferrofluidic seal. For example, the core 128 may have an annular channel in the innermost surface (or outermost if the core encircles the pole pieces 127) of the core 128. Thus, when a shaft is inserted through a hole in the center of the core 128, an annular cavity 134 may be defined by the annular channel and the outer surface of the shaft that bounds the shaft. O-rings 1A32a and 132b (or other suitable seals) may be used to seal the core 128 to the shaft and prevent axial leakage of the coolant from the cavity 134. An inlet and an outlet may be fluidically connected with the cavity 134, e.g., positioned diametrically opposite one another, so as to allow coolant to be flowed into, through, and then out of the cavity 134.

Returning to the wafer handling robot 106, one of the one or more rotational joints 112 may serve as a base rotational joint that rotatably connects one of the arm links 116 with the robot arm base 108. In this example, the first rotational joint 112a serves as the base rotational joint. In implementations having multiple arm links 116, each arm link 116 may be rotatably connected with another one of the arm links 116 by a corresponding rotational joint 112. For example, in the depicted example robot arm assembly 110, the first arm link 116a is rotatably connected with the second arm link 116b by the second rotational joint 112b and the second arm link 116b is rotatably connected with the third arm link 116c by the third rotational joint 112c. The fourth arm link 116d and the fifth arm link 116e are both rotatably connected with the third arm link 116c by the fourth rotational joint 112d and the fifth rotational joint 112e, respectively. In this example, the fourth rotational joint 112d and the fifth rotational joint 112e are coaxial with one another such that the fourth arm link 116d and the fifth arm link 116e are both rotatable relative to the third arm link 116c about a common rotational axis,

One or more of the arm links 116 of the robot arm assembly 110 may serve as an end effector link, e.g., that terminates in an end effector 176 that may be used to support a semiconductor wafer (or other article) that is to be transported by the robot arm assembly 110. In the example robot arm assembly 110, there are two end effector arm links-the fourth arm link 116d (supporting a first end effector 176a) serves as a first end effector arm link, and the fifth arm link 116e (supporting a second end effector 176b) serves as a second end effector link. In some instances, the end effector link(s) may be connected with another arm link that directly supports the end effector link(s) with respect to the remainder of the robot arm assembly. The arm link that directly supports the end effector link(s) may be referred to as a “forearm link.” It will be understood that in some instances, the robot arm assembly may feature a single arm link, in which case the end effector arm link may simply be directly connected with the robot arm base 108.

The various arm links 116 shown are each independently drivable using a corresponding motor 162, although in some multi-link robot arm assemblies, two or more of the arm links may be kinematically coupled such that they move together in a kinematically linked manner, thereby allowing both arm links to be caused to move relative to the respective arm links that support them responsive to a single motive input, e.g., a rotational input from a single motor.

For example, as can be more clearly seen in FIG. 1A, the first arm link 116a contains a first motor 162a that includes a first stator 164a and a first rotor 166a. The first rotor 166a may be connected with a shaft that protrudes up from the robot arm base 108 and that is fixed in space with respect to the robot arm base 108. The first stator 164a may be connected with the first arm link 116a such that when the first motor 162a is provided with power, the first rotor 166 and the first stator 164a may be caused to undergo rotation relative to one another, thereby causing the first arm link 116a to rotate relative to the robot arm base 108, Of course, the configuration shown may also be reversed, e.g., with the first motor 162a located in the robot arm base 108 and the shaft instead extending downward from the first arm link 116a and into the robot arm base 108 and the first motor 162a.

The first arm link 116a may also include, as shown in FIG. 1A, a second motor 162b that includes a second stator 164b and a second rotor 166b. The second stator 164b may be fixed in space with respect to the first arm link 116a, while the second rotor 166b may be fixed in space with respect to the second arm link 116b. For example, the second arm link 116b may have a shaft that extends down into the second arm link 116b and the second rotor 166b. When the second motor 162b is actuated, causing relative rotation between the second stator 164b and the second rotor 166b, the resulting rotational output may cause the second arm link 116b to rotate relative to the first arm link 116a.

The first rotational joint 112a, it can be seen, may include a pair of rotational bearings 136a and 136a′ that may rotatably support the first arm link 116a relative to the robot arm base 108. The first rotational joint 112a may also include a ferrofluidic seal 124a that may seal between the first arm link 116a and the shaft that protrudes from the robot arm base 108. It will be noted that the rotational bearings 136a and 136a′ are sealed within the first arm link 116a by the ferrofluidic seal 124a.

As can be seen more clearly in FIG. 1A, two coolant flow path segments 120a and 120b are routed from the robot arm base 108, through the first rotational joint 112a, and into the first arm link 116a. For example, the shaft that extends up from the robot arm base 108 and into the first arm link 116a may have a bore or passage through it through which the coolant flow path segments 120a and 120b may be routed. There may be a clearance gap between an interior surface of the first arm link 116a that faces the end of the shaft of the robot arm base 108 so as to allow the coolant flow path segments 120 to be routed to components or locations that are radially outboard of the first rotational joint 112a. One or more of the coolant flow path segments 120a may be fluidically connected with a coolant source 194, while one or more of the coolant flow path segments 120b may be fluidically connected with a coolant return 196. Alternatively, the coolant flow path segments 120a and 120b may be fluidically connected with, for example, an external heat exchanger or coolant reservoir and a pump that circulates the coolant from the heat exchanger or reservoir and through the coolant flow path segments before returning it to the heat exchanger or reservoir. Coolants that may be used may include, for example, water, water mixed with antifreeze, Galden, or other suitable fluids.

In a similar manner, one or more cables 118 may also be routed through the first rotational joint 112a. The one or more cables 118 may be electrical cables that are configured to transmit electrical signals, e.g., power and/or data signals, to components within the robot arm assembly 110. The one or more cables 118 may be connected with a controller 198 which may provide such power and/or data signals in order to control the wafer-handling robot.

The coolant flow path segments 120 may, generally speaking, be configured to route coolant fluid to one or more cooling features that may be located within the robot arm assembly. For example, the ferrofluidic seal 124a may have a first ferrofluidic seal cooling feature 144a that is positioned adjacent to, or that encircles, the ferrofluidic seal 124a. In this example, the first ferrofluidic seal cooling feature 144a includes an annular cavity that extends around, and that is partially defined by, the outer perimeter of the ferrofluidic seal 124a. The first ferrofluidic seal cooling feature 144a may, for example, have an inlet feature that may receive coolant delivered to the first ferrofluidic seal cooling feature 144a by one of the coolant flow path segments 120a and an outlet feature that may deliver coolant from the first ferrofluidic seal cooling feature 144a to one of the coolant flow path segments 120b. The coolant flow path segments 120a and 120b may thus be used to flow coolant through the first ferrofluidic seal cooling feature 144a, thereby cooling the ferrofluidic seal 124a.

As shown, the first ferrofluidic seal cooling feature 144a is an annular void that encircles the ferrofluidic seal 124a. The annular void, in this case, is defined by an annular channel in the outer surface of the core of the ferrofluidic seal 124a and another annular channel in the interior surface of the bore in the first arm link 116a that receives the ferrofluidic seal 124a. However, other implementations may feature such a channel in one or the other of such locations. Additionally, other arrangements of ferrofluidic seal cooling features may be used as well, e.g., C-shaped cooling features in which the inlet and outlet are positioned at opposite ends of a C-shaped passage that encircles, or mostly encircles, the ferrofluidic seal. Generally speaking, a ferrofluidic seal cooling feature may at least include one or more passages, e.g., a C-shaped or annular-sector-shaped passage, two C-shaped passages forming an annular passage, etc., that lie at least partially within a tubular zone that has a center axis that is coaxial with the rotational axis of the rotational joint that features the ferrofluidic seal in question. Such a tubular zone may, in some cases, encircle one or more surfaces of the ferrofluidic seal being cooled that face radially inward towards the rotational axis thereof. In other instances, the tubular zone may instead be encircled by one or more surfaces of the ferrofluidic seal being cooled that face radially inward towards the rotational axis thereof. In other implementations, such a passage or passages may simply be positioned adjacent to the ferrofluidic seal being cooled. In some implementations, at least part of such a passage or passages may be defined by surfaces of the ferrofluidic seal being cooled, e.g., surfaces thereof that face radially outward or radially inward, depending on the positioning of the ferrofluidic seal cooling feature relative to the ferrofluidic seal being cooled.

The second rotational joint 112b, similar to the first rotational joint 112a, has a pair of rotational bearings 136b and 136b′ that may rotatably support the second arm link 116b relative to the first arm link 116a. The second rotational joint 112b may also include a second ferrofluidic seal 124b that may seal between the first arm link 116a and the shaft that protrudes from the second arm link 116b. A second ferrofluidic cooling feature 144b that is fluidically connected with, and fluidically interposed between, two of the coolant flow path segments 120, is positioned so as to provide cooling to the second ferrofluidic seal 124b.

It will be appreciated that the other rotational joints 112c, 112d, and 112e in this example are also equipped with corresponding ferrofluidic cooling features, thereby allowing the ferrofluidic seals of each of the rotational joints 112 to be actively cooled by its own dedicated ferrofluidic seal cooling feature 144. In some implementations, ferrofluidic seals 124 that are positioned close to one another, e.g., such as the ferrofluidic seals 124d and 124e, may share a common ferrofluidic seal cooling feature, e.g., such ferrofluidic seals may be positioned close enough that heat from one ferrofluidic seal may flow through the other ferrofluidic seal to reach a ferrofluidic seal cooling feature that encircles them both.

Generally speaking, the cooling features discussed herein, such as the ferrofluidic seal cooling features 144, may each be fluidically connected with, and fluidically interposed between, at least two coolant flow path segments such that coolant may be delivered to the cooling feature via one of those coolant flow path segments and then evacuated from that cooling feature by the other one or ones of those coolant flow path segments. Each coolant flow path segment 120 may, for example, be defined by one or more components such as lengths of flexible tubing (such as polymeric tubing), lengths of rigid tubing, fittings, pass-through connectors (or portions thereof), and flow-splitting devices (or portions thereof).

As can be seen in this example, there are multiple coolant flow path segments 120a and 120b, with the coolant flow path segments 120a providing for coolant delivery to the various cooling features used, and the coolant flow path segments 120b providing for coolant recovery from those same cooling features. In this example, the various coolant flow path segments 120a and 120b are each fluidically connected with respective junction blocks 122 that allow the coolant flow to be subdivided or split off between different coolant flow path segments 120a or the coolant flow from different coolant flow path segments 120b to be merged or joined. Such junction blocks 122 are arranged in the robot arm assembly 110 such that the junction blocks 122 are all connected in series by corresponding coolant flow path segments 120a and 120b, with additional coolant flow path segments 120 leading from each junction block 122 to nearby cooling features so as to supply coolant to those cooling features in parallel.

As can be seen, another pair of coolant flow path segments 120 passes from the first arm link 116a to the second arm link 116b via the second rotational joint 112b. Such coolant flow path segments 120 may, for example, pass up through a hollow shaft that extends down into the first arm link 116a from the second arm link 116b.

The second arm link 116b is shown in more detail in FIG. 1B. As can be seen, the second arm link 116b has a different motor configuration inside, with a third motor 162c (which is represented by a box but which would typically include a rotor and a stator as with the first motor 162a and the second motor 162b) being configured to provide rotational input to the third arm link 116c via a pulley system. For example, the third motor 162c may have a rotational output that is connected with a pulley 168c that is, in turn, kinematically coupled with a pulley 168c′ by a belt 170c. The belt 170c may, for example, be a steel belt. Steel belts are typically used in robot arm assemblies used in vacuum since such belts do not outgas and generate minimal amounts of particulate contamination. However, since the interior of the second arm link 116b is fluidically isolated from the vacuum environment surrounding the robot arm assembly 110 by the ferrofluidic seals 124, it is also possible to use other types of material for the belt 170c, such as polymeric belts, textile-reinforced polymeric belts, etc. that would normally be avoided in robots designed for vacuum environments. It will be noted that there is no pulley 168a or pulley 168b in the depicted example robot arm assembly 110; the omission of the a/b suffixes was deliberate to allow the pulleys 168c and 168c′ to share the same suffix as the motor 162 that they are associated with.

When the third motor 162c is caused to actuate, e.g., responsive to power and/or control signals received via the cable 118, the rotation of the pulley 168c causes the belt 170c to drive the pulley 168c′, thereby causing the third arm link 116c to rotate relative to the second arm link 116b.

As can be seen, the third rotational joint 112c, as with the rotational joints 112 discussed earlier, includes a pair of rotational bearings 136c and 136c′ that support the third arm link 116c relative to the second arm link 116b, e.g., via a shaft that protrudes from the underside of the third arm link 116c. The third rotational joint 112c also includes a third ferrofluidic seal 124c that seals between the third arm link 116c, e.g., between the shaft protruding from the underside of the third arm link 116c, and the second arm link 116b, thereby sealing the interior of the second arm link 116b against potential leaks through the third rotational joint 112c.

Also shown is a third ferrofluidic seal cooling feature 144c that is configured to cool the third ferrofluidic seal 124c. The third ferrofluidic seal cooling feature 144c may, for example, be similar to the ferrofluidic seal cooling features 144 discussed earlier, and may be fluidically connected with, for example, coolant flow path segments 120a and 120b that lead to a second junction block 122b (with the first junction block being the junction block 122a).

In addition to the third ferrofluidic seal cooling feature 144c, the second arm link 116b also includes another type of cooling feature, e.g., a third motor cooling feature 146c (no first or second motor cooling feature is featured in this example—the “third” ordinal indicator is used to make the motor cooling feature share the same ordinal indicator as the motor it cools). The third motor cooling feature 146c may be positioned adjacent to, or so as to encircle, the third motor 162c and may, for example, be a cooling jacket, e.g., an enclosure that may contact the motor around some or all of its circumference and which may have one or more internal cavities through which coolant supplied from one of the coolant flow path segments 120 may be flowed in order to remove heat from the third motor cooling feature 146c, thereby cooling the third motor 162c. The cooling jacket may, for example, be similar in structure to the ferrofluidic seal cooling features 144 discussed earlier, e.g., having an internal cavity or passage(s) that are similar in structure. It will also be understood that the ferrofluidic seal cooling features 144 may, instead of being integrated into the structure of the arm links 116 that contain them, be provided in a separate part, e.g., similar to the cooling jacket that provides the third motor cooling feature 146c.

As can be seen, coolant may be flowed into the third motor cooling feature 146c via one or more coolant flow path segments 120 and then flowed out of the third motor cooling feature 146c via one or more other coolant flow path segments 120.

In some implementations, as shown in an alternate FIG. 1B′, the use of ferrofluidic seals or other vacuum-rated rotational seals may be used in conjunction with additional fluid flow lines for purposes other than, or in addition to, cooling. For example, in some implementations, a fluid flow line or lines for providing a purge gas, e.g., an inert (noble or otherwise non-reactive with process chemistry, such as, in many cases, nitrogen) gas may be routed in the interior of the robot arm assembly.

In FIG. 1B′, the second rotational joint 112b has been augmented with a purge gas bleed feature that allows a purge gas provided by a purge gas line 184 to be provided to a purge gas plenum 186 that may, in turn, distribute purge gas to one or more purge gas outlets 188 that are arranged around or about the second rotational joint 112b. The purge gas plenum 186 may, for example, be generally annular in shape or otherwise extend around most or all of the circumference of the second rotational joint (for example, the purge gas plenum may be provided by two arcuate plenums/passages that have a common center point and are each provided purge gas from a corresponding inlet). The purge gas line 184 may, like the coolant flow path segments, be provided at least partially by way of a flexible tube.

The three circular cross-sections shown at bottom right of FIG. 1B′ depict various alternate implementations of a purge gas bleed feature. The left example is similar to that shown in FIG. 1B′ at far left, with a plurality of discrete purge gas outlets 188 arranged in a circular array about the exterior of the shaft portion of the second arm link 116b such that purge gas, when flowed into the purge gas plenum 190, is caused to flow radially outward around the circumference of the shaft portion in the gap between the first arm link 116a and the second arm link 116b in the vicinity of the second rotational joint 112b. Such purge gas flow may act to protect the second ferrofluidic seal 124b from potential exposure to process gas residues that may otherwise come into contact with, and potentially degrade, the second ferrofluidic seal 124b.

The middle cross-section shown in FIG. 1B′ is similar in design except that instead of the purge gas outlets 188 being provided by a plurality of discrete passages arranged about the shaft portion of the second arm link 116b, there is a single purge gas outlet 188 that is provided by a thin circumferential slit that spans between the exterior of the shaft portion of the second arm link 116b and the purge gas plenum 186.

The right cross-section shown in FIG. 1B′ is similar in design to the left-most circular cross-section in FIG. 1B except that it has a plurality of purge gas plenums 186 and a plurality of different sets of purge gas outlets 188. For example, purge gas may be provided to a first purge gas plenum 186a by a purge gas line 184 and may then pass from the first purge gas plenum 186a to a second purge gas plenum 186b by way of first purge gas outlets 188a. The purge gas may then pass from the second purge gas plenum 186b to the region surrounding the shaft portion of the second arm link 116b by way of second purge gas outlets 188b.

As can be seen, the use of multiple purge gas plenums 186 arranged so as to provide more or less concentric purge gas plenum zones (each plenum zone having an annular plenum or multiple arcuate plenums lying within an annular zone) that fluidically communicate with each other by way of purge gas outlets that each span between two adjacent purge gas plenums allows for the purge gas delivered thereby to be more evenly circumferentially distributed between the last set of purge gas outlets before being released into the ambient environment around the robot arm assembly. In such arrangements, each set of purge gas outlets communicating between two adjacent purge gas plenum zones may be arranged so as to be circumferentially equidistantly positioned between two adjacent purge gas outlets 188, thereby resulting in each possible shortest flow path between the purge gas inlet(s) and each outermost purge gas outlet 188 to be closer to the average such flow path length, thereby resulting in more evenly distributed purge gas.

It will be understood that while the purge gas bleed feature discussed above is shown only being implemented on the second rotational joint 112b, similar such features may be implemented in any rotational joint of a robot arm assembly, including all of the rotational joints of a robot arm assembly, or at least a plurality of rotational joints of a robot arm assembly.

FIG. 1C depicts a detail view of the third arm link 116c, the fourth arm link 116d, and the fifth arm link 116e. The third arm link 116c includes a fourth motor 162d and a fifth motor 162e, which are shown as being kinematically connected with the fourth arm link 116d and the fifth arm link 116e, respectively. The fourth motor 162d, for example, may be configured to drive a pulley 168d that is configured to drive a pulley 168d′ via a belt 170d in order to cause the fourth arm link 116d to rotate relative to the third arm link 116c. Similarly, the fifth motor 162e may, for example, be configured to drive a pulley 168e that is configured to drive a pulley 168e′ via a belt 170e in order to cause the fifth arm link 116e to rotate relative to the third arm link 116c.

As shown in FIGS. 1 and 1C, a fourth motor cooling feature 146d and a fifth motor cooling feature 146e may be positioned so as to encircle, or be adjacent to, the fourth motor 162d and the fifth motor 162e, respectively. These motor cooling features may, for example, have characteristics similar to those discussed earlier with respect to the third motor cooling feature 146c.

As noted earlier, the fourth arm link 116d and the fifth arm link 116e may be rotatably connected with the third arm link 116c by way of a fourth rotational joint 112d and a fifth rotational joint 112e, respectively.

As can be seen, the fourth rotational joint 112d, as with the rotational joints 112 discussed earlier, includes a pair of rotational bearings 136d and 136d′ that support the fourth arm link 116d relative to the third arm link 116c, e.g., via a shaft portion 178d that protrudes from the underside of a body portion 180d of the fourth arm link 116d. The fourth rotational joint 112d also includes a fourth ferrofluidic seal 124d that seals between the fourth arm link 116d, e.g., between the shaft portion 178d protruding from the underside of the body portion 180d of the fourth arm link 116d, and a shaft portion 178e that protrudes from the underside of a body portion 180e of the fifth arm link 116e, thereby sealing the interior of the third arm link 116c against potential leaks through the fourth rotational joint 112d. Similarly, the fifth rotational joint 112e includes a pair of rotational bearings 136e and 136e′ that support the fifth arm link 116e relative to the third arm link 116c, e.g., via the shaft portion 178e that protrudes from the underside of the body portion 180e of the fifth arm link 116e. The fifth rotational joint 112e also includes a fifth ferrofluidic seal 124e that seals between the fifth arm link 116e, e.g., between the shaft portion 178e protruding from the underside of the body portion 180e of the fifth arm link 116e, third arm link 116c, thereby sealing the interior of the third arm link 116c against potential leaks through the fifth rotational joint 112e.

The fourth rotational joint 112d and the fifth rotational joint 112e are, as noted earlier, coaxially arranged. Thus the shaft portion 178d actually extends through the shaft portion 178e and protrudes beyond the end of the shaft portion 178e, thereby allowing the shaft portion 178d to be connected with the pulley 168d′. The shaft portion 178e is rotatably supported relative to the third arm link 116c by the rotational bearings 136e and 136e′, while the shaft portion 178d is rotatably supported relative to the shaft portion 178e by way of the rotational bearings 136d and 136d′. As the rotational bearings 136d, 136d′, 136e, and 136e′ are all positioned so as to have a common rotational axis, such an arrangement effectively allows both the fourth arm link 116d and the fifth arm link 116e to be rotatable relative to both the third arm link 116c and each other by way of the fourth rotational joint 112d and the fifth rotational joint 112e, respectively,

As shown in FIGS. 1 and 1C, the fourth arm link 116d and the fifth arm link 116e each house a respective sensor 172a and 172b. The sensors 172 may, for example, be optical sensors, such as imaging sensors. Each sensor 172 may be configured to obtain data, e.g., images, from a region beneath that sensor. For example, such a sensor 172 may be used to obtain image data regarding a component within a semiconductor processing chamber, e.g., an image of a fiducial located on such a component, that may assist with calibrating the robot arm system with regard to where such a component is located relative to the robot arm base 108. Such a sensor may also be used to obtain data on other aspects of the chamber as well, e.g., the condition of the pedestal or an edge ring located within the chamber. It will be appreciated that the sensors 172 may also or alternatively be placed in other orientations within the robot arm links 116d and 116e, e.g., facing upward or outward instead of downward. Such a configuration may allow the sensors 172 to obtain data regarding components or features such as the chamber walls or a showerhead that may be within such a processing chamber.

Also visible in FIGS. 1 and 1C are sensor cooling features 148a and 148b. The sensor cooling features 148 may each be placed adjacent to, or so as to encircle, a portion of one of the sensors 172. In this example, the sensor cooling features 148a and 148b are cooling blocks with serpentine cooling channels routed therethrough. The cooling blocks are placed against the sensors 172 such that heat from the sensors 172a and 172b is conducted into the sensor cooling features 148a and 148b, respectively. Coolant that is flowed through the sensor cooling features 148 may then act to remove the heat from the sensor cooling features 148.

In a coaxial rotational joint configuration such as that shown in FIGS. 1 and 1C, the routing of the coolant flow path segments for the cooling features that may be located within the arm links 116 that are supported by the coaxial rotational joints 112 may be challenging. For example, it may be possible to route the coolant flow path segments 120 that lead to the fourth arm link 116d through the center of the shaft portion 178d and then out of the top of the shaft portion 178d and into the interior of the fourth arm link 116d, where such coolant flow path segments 120 may fluidically connect with a cooling feature. However, the routing of the coolant flow path segments that lead to a cooling feature that is located in the fifth arm link 116e may be more challenging. For example, if such coolant flow path segments also pass through the center of the shaft portion 178d, they will somehow need to pass through the fifth rotational joint in a radial direction (as opposed to axial direction) in order to reach the interior of the fifth arm link 116e.

In order to facilitate this, the shaft portion 178d may be provided with an opening (or openings) that extends in a generally radial manner from the interior of the shaft portion 178d to the exterior surface of the shaft portion 178d, thereby allowing coolant flow path segments 120 to be routed from the interior of the shaft portion 178d to the exterior of the shaft portion 178d. The opening, e.g., opening 182 in FIG. 1C, may be located in such that the ferrofluidic seal that seals between the two coaxial shaft portions 178d and 178e is interposed between the opening 182 and the body portion of the fourth arm link 116d. This allows the opening to be located within the region of the robot arm assembly 110 that is fluidically isolated from the vacuum environment that may surround the robot arm assembly 110. This allows coolant flow path segments 120 to pass into the fifth arm link 116e from the interior of the shaft portion 178d of the fourth arm link 116d.

In some instances, the opening 182 may extend about the circumference of the shaft portion for a sector of arc, e.g., the opening 182 may be a radial slot that extends along an arc that is coradial with the exterior surface of the shaft portion 178d, e.g., through an angle of arc of at least 45°, at least 60°, at least 75°, at least 90°, at least 115°, at least 130°, or at least 180°. Such a slot may provide clearance to allow the shaft portion 178d and the shaft portion 178e to rotate relative to one another without causing undue shear stress in the coolant flow path segments 120 that pass through the opening 182. The sector of arc that the opening extends across may, for example, be selected to as to be nominally similar to the sector of arc that the fourth arm link 116d and the fifth arm link 116e may swing through relative to one another during normal use.

FIG. 1C′ depicts an alternate implementation in which there is an additional cooling feature type included—an arm link cooling feature. As shown in FIG. 1C′, which portrays a detail view of the region marked C′ in FIG. 1C, the fourth arm link 116d is equipped with an arm link cooling feature 151. The arm link cooling feature 151, in this example, is a cooling block that has one or more coolant passages within it that are provided coolant from corresponding coolant flow path segments 120a and 120b. The cooling passages may, as shown, follow a serpentine path within the cooling block. In other implementations, such cooling passages may be formed, e.g., machined, directly in the material of the arm link itself. The arm link cooling feature 151 may, in some cases, extend along the entire length of the arm link or may extend along only a portion thereof, e.g., along the half of the arm link closest to the end effector(s). The arm link cooling feature 151 may also extend along the bottom and/or side surfaces of the arm link.

It will be appreciated that while the arm link cooling feature 151 is shown as being present in only one arm link in FIG. 1C′, such arm link cooling features may be implemented in additional or other arm links as well, e.g., in all arm links or a subset thereof. Such cooling features may allow a robot arm assembly to shed heat that may be transferred to the components thereof, e.g., through handling elevated-temperature wafers. For example, if a robot arm assembly is used to pick up wafers that are still significantly hot, e.g., at 200+° C., 300+° C., and/or 400+°C., the heat that radiates and conducts from those wafers may be transferred to the end effectors that carry them and then to the arm links via conduction. Since such robot arm assemblies may commonly operate in a vacuum environment, it may be difficult for the robot arm assemblies to shed heat that is transmitted thereto into the ambient atmosphere. Thus, arm link cooling features may provide a valuable ability to cool robot arm assemblies used in vacuum environments and/or that are used in transferring hot wafers.

It will be appreciated the features that are discussed above with respect to the various cooling features and components to be cooled within the robot arm assembly of FIGS. 1 through 1C may be implemented in various contexts. For example, some robot arm assemblies may only include ferrofluidic seal cooling features, while other robot arm assemblies may only include sensor cooling features. It is not necessarily the case that a robot arm assembly will have all four types of cooling features that are discussed above with respect to FIGS. 1 through 1C, and robot arm assemblies with only ferrofluidic seal cooling features, only motor cooling features, only sensor cooling features, only arm link cooling features, only ferrofluidic seal cooling features and motor cooling features, only ferrofluidic seal cooling features and arm link cooling features, only ferrofluidic seal cooling features and sensor cooling features, only motor cooling features and arm link cooling features, only sensor cooling features and arm link cooling features, only ferrofluidic seal cooling features, motor cooling features, and sensor cooling features, only ferrofluidic seal cooling features, motor cooling features, and arm link cooling features, only ferrofluidic seal cooling features, sensor cooling features, sensor cooling features, or arm link cooling features, only motor cooling features, sensor cooling features, or arm link cooling features are also considered to be within the scope of this disclosure. It will also be understood that cooling features other than the specific examples discussed herein may be included in such a robot arm assembly. Moreover, it will be appreciated that the concepts discussed herein with respect to the example robot arm assembly 110 of FIGS. 1 through 1C may also be implemented in robot arm assemblies having only a single arm link, two arm links, three arm links, four arm links, five arm links, six arm links, seven arm links, eight arm links, nine arm links, etc. It will also be appreciated that vacuum-compatible seals other than ferrofluidic seals may be used in place of the ferrofluidic seals discussed herein, if desired.

The above discussion references coolant flow path segments without generally distinguishing between inlet coolant flow path segments and outlet coolant flow path segments. This is because the nature of any particular coolant flow path segment may vary depending on the context in which it is viewed. For example, in the example of FIGS. 1 through 1C, the coolant flow path segments 120a may all be used to supply coolant to the various cooling features within the depicted robot arm assembly 110, while the coolant flow path segments 120b may all be used to return coolant from those same cooling features (or vice versa). In the example of FIGS. 1 through 1C, the coolant flow path segments 120a are generally arranged in parallel with the coolant flow path segments 120b, thereby resulting in each coolant flow path segment 120 serving only one purpose with respect to coolant supply to a cooling feature or coolant return from a cooling feature. However, other arrangements, e.g., in which coolant is delivered to multiple cooling features in series, may have coolant flow path segments that may serve multiple purposes, e.g., a single coolant flow path segment may serve as a coolant supply with respect to a cooling feature that is “downstream” of the coolant flow path segment and as a coolant return from another cooling feature that is “upstream” of the coolant flow path segment.

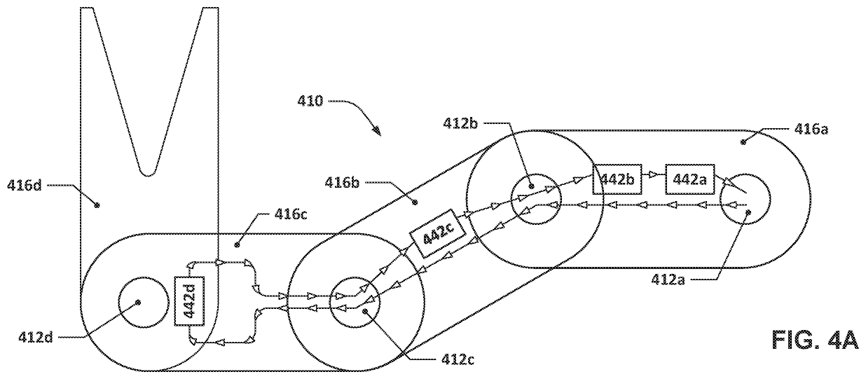

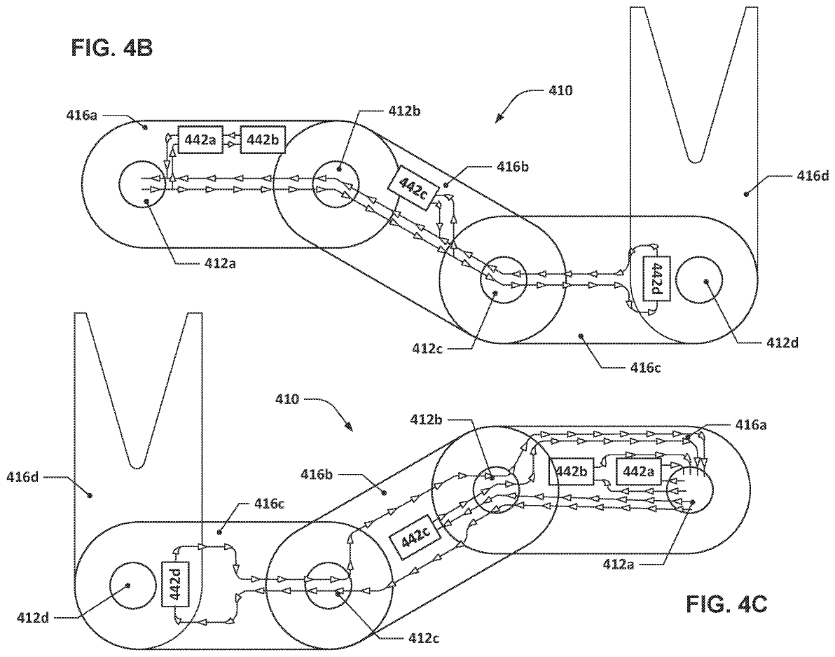

FIGS. 4, which include FIG. 4A, FIG, 4B, and FIG, 4C, depict diagrams showing various coolant flow path segment routing options that may, for example, be used to provide coolant to, and receive coolant from, the cooling features in a robot arm assembly.

In FIG. 4, an example robot arm assembly 410 is shown. The example robot arm assembly 410 includes a first arm link 416a, a second arm link 416b, a third arm link 416c, and a fourth arm link 416d. The first arm link 416a is rotatably connected with a robot arm base (not shown) via a first rotational joint 412a and with the second arm link 416b via a second rotational joint 412b. Similarly, the third arm link 416c is rotatably connected with the second arm link 416b via a third rotational joint 412c and is rotatably connected with the fourth arm link 416d via a fourth rotational joint 412d. There are a number of cooling features 442 positioned at different locations within the robot arm assembly 410, including, for example, a first cooling feature 442a and a second cooling feature 442b in the first arm link 416a, a third cooling feature 442c in the second arm link 416b, and a fourth cooling feature 442d in the third arm link 416c.

In FIG. 4, the coolant flow path segments are represented by lines with triangles indicating flow direction that connect to the various cooling features and that are routed through the rotational joints 412.

In FIG. 4A, it can be seen that one coolant flow path segment fluidically connects with the inlet to the cooling feature 442d, passing through the three rotational joints 412a-412c. It can be further seen that additional coolant flow path segments fluidically connect the outlet of each of the three cooling features 442d-442b with the inlet of the cooling feature 442c-442a that is “downstream” therefrom. The coolant flow path segment that leads from the outlet of the first cooling feature 442a may, for example, exit the robot arm assembly 410 via the robot arm base, e.g., and empty into an external heat exchanger or other heat dissipation system. Thus, the four cooling features 442 are fluidically connected in series.

In FIG. 4B, it can be seen that there are two main coolant flow path segments that extend from the first rotational joint 412a through the second rotational joint 412b and the third rotational joint 412c that fluidically connect with the cooling feature 442d, thereby allowing coolant to be circulated through the cooling feature 442d. Additional coolant flow path segments are shown splitting off of these two main coolant flow path segments and leading to the cooling feature 442c and the cooling features 442a and 442b. Thus, coolant is delivered to the cooling features 442a, 442c, and 442d in parallel. The cooling features 442a and 442b, however, are fluidically connected in series. Thus, the coolant flow path segments may be arranged so as to fluidically connect to cooling features in a parallel and/or series manner.

In FIG. 4C, it can be seen that completely separate coolant flow path segments are provided for each cooling feature 442a through 442d. Such an arrangement allows coolant to be delivered at different rates (which may be varied as desired through the use of flow metering devices or valves) to different cooling features 442, although the increased amount of hardware required to route eight separate flow paths through the first rotational joint 412a may take more space than is required by the two-flow path implementations of other examples.

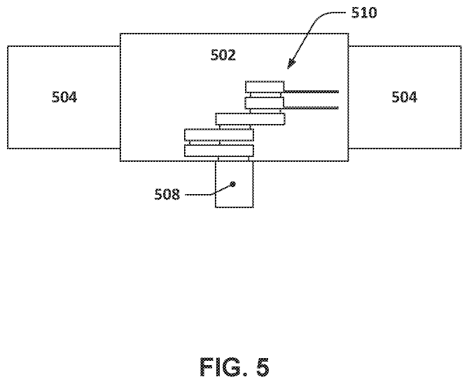

As discussed earlier, wafer-handling robots such as those described above may be used in a VTM. FIG. 5 depicts a diagram of a VTM 502 that has a plurality of processing chambers 504 attached thereto, e.g., via slit valves or other closeable apertures (not shown). A wafer-handling robot with a robot arm assembly 510 and a robot arm base 508 may be mounted to the VTM 502 such that the robot arm base 508 is mounted to the exterior of the VTM 502 and the robot arm assembly 510 is located in the interior of the VTM 502, e.g., in a vacuum environment. The robot arm assembly 510 may, for example, include ferrofluidic seals and cooling features, as discussed with regard to the examples discussed earlier herein.

It will be understood that while the present disclosure has focused on wafer-handling robots as examples of robots that may incorporate ferrofluidic seals or other vacuum-compatible rotational seal technology to allow the interior of a robot arm to be kept at atmospheric (or at least higher) pressure, thereby facilitating the use of flexible cooling lines within the robot arm to permit fluidic cooling of components within the robot arm, the principles and concepts discussed herein may be applied in robot arms used under vacuum conditions for other purposes as well. This disclosure is to be understood to encompass such alternative embodiments as well.

The control of a wafer-handling robot such as that described herein may be facilitated through the use of a controller that may be included as part of a semiconductor processing tool having the wafer-handling robot or that may be integrated into the wafer-handling robot itself. The systems discussed above may be integrated with electronics for controlling their operation before and after processing of a semiconductor wafer or substrate. The electronics may be referred to as the “controller,” which may control various components or subparts of the system or systems. The controller, depending on the processing requirements and/or the type of system, may be programmed to control any of the systems disclosed herein, including operation of the various motors and/or sensors that may be incorporated into a wafer-handling robot, etc.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular wafer transfer operation within a VTM using a wafer-handling robot as disclosed herein.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber, e.g., a VTM, in communication with one or more integrated circuits located remotely (such as at the platform level or as part of a remote computer) that combine to control a wafer transfer operation in a VTM using a wafer-handling robot.

Without limitation, example VTMs having wafer-handling robots such as those discussed herein may be connected with one or more other pieces of equipment, including a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, or any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers, e.g., FOUPs, to and from tool locations and/or load ports in a semiconductor manufacturing factory.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for Illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
a robot arm base;
a robot arm assembly including one or more arm links and a first set of one or more rotational joints, each rotational joint of the first set of one or more rotational joints including a corresponding vacuum-compatible seal;
components defining a plurality of coolant flow path segments; and
a first set of one or more cooling features, each cooling feature in the first set of one or more cooling features fluidically connected with, and fluidically interposed between, at least two of the coolant flow path segments, wherein:
a base rotational joint of the one or more rotational joints rotatably connects a first arm link of the one or more arm links to the robot arm base, and
at least two of the coolant flow path segments extend from the robot arm base, through the base rotational joint, and into at least the first arm link.

2. The apparatus of claim 1, wherein:
the one or more vacuum-compatible seals includes at least a first vacuum-compatible seal, and
the one or more cooling features includes one or more vacuum-compatible seal cooling features, the one or more vacuum-compatible seal cooling features including a first vacuum-compatible seal cooling feature that is configured to cool the first vacuum-compatible seal when a coolant is flowed into the first vacuum-compatible seal cooling feature via at least one of the coolant flow path segments and out of the first vacuum-compatible seal cooling feature via at least one other coolant flow path segment of the coolant flow path segments.

3. The apparatus of claim 2, wherein:
the first vacuum-compatible seal cooling feature includes a passage that extends through at least part of a tubular zone that has a centerline that is coaxial with a rotational axis of the one of the one or more rotational joints that includes the first vacuum-compatible seal, and
the tubular zone encircles one or more surfaces of the first vacuum-compatible seal that face radially inward towards the rotational axis of the one of the one or more rotational joints that includes the first vacuum-compatible seal.

4. The apparatus of claim 3, wherein the passage is bounded, at least in part, by one or more surfaces of the first vacuum-compatible seal that face radially outward from the rotational axis of the one of the one or more rotational joints that includes the first vacuum-compatible seal.

5. The apparatus of claim 2, wherein:
the first vacuum-compatible seal cooling feature includes a passage that extends through at least part of a tubular zone that has a centerline that is coaxial with a rotational axis of the one of the one or more rotational joints that includes the first vacuum-compatible seal, and
the tubular zone is encircled by one or more surfaces of the first vacuum-compatible seal that face radially inward towards the rotational axis of the one of the one or more rotational joints that includes the first vacuum-compatible seal.

6. The apparatus of claim 5, wherein the passage is bounded, at least in part, by the one or more surfaces of the first vacuum-compatible seal that face radially inward towards the rotational axis of the one of the one or more rotational joints that includes the first vacuum-compatible seal.

7. (canceled)

8. The apparatus of claim 1, wherein:
the robot arm assembly includes a first motor, and
the one or more cooling features includes one or more motor cooling features, the one or more motor cooling features including a first motor cooling feature that is positioned adjacent to or encircling a portion of the first motor and configured to cool the first motor when a coolant is flowed into the first motor cooling feature via at least one of the coolant flow path segments and out of the first motor cooling feature via at least one other coolant flow path segment of the coolant flow path segments.

9. The apparatus of claim 1, wherein the one or more cooling features includes one or more arm link cooling features, the one or more arm link cooling features including a first arm link cooling feature that is positioned adjacent to, or within, material forming one of the one or more arm links and configured to cool that arm link when a coolant is flowed into the first arm link cooling feature via at least one of the coolant flow path segments and out of the first arm link cooling feature via at least one other coolant flow path segment of the coolant flow path segments.

10. The apparatus of claim 9, wherein the first arm link cooling feature extends along at least half of the length of the arm link the material of which the first arm link cooling feature is positioned adjacent to or within.

11. The apparatus of any one of claims 1 through 10, further comprising a first sensor located within one of the one or more arm links, the one or more cooling features includes one or more sensor cooling features, the one or more sensor cooling features including a first sensor cooling feature that is positioned adjacent to or encircling a portion of the first sensor and configured to cool the first sensor when a coolant is flowed into the first sensor cooling feature via at least one of the coolant flow path segments and out of the first sensor cooling feature via at least one other coolant flow path segment of the coolant flow path segments.

12. The apparatus of claim 11, wherein the first sensor is an optical sensor or an imaging sensor.

13. (canceled)

14. The apparatus of claim 11, wherein:
the one or more arm links includes a first end effector arm link having a first end effector, and
the first sensor is in the first end effector arm link.

15. The apparatus of claim 14, wherein the first sensor is oriented to collect data from a location underneath the first end effector arm link.

16. The apparatus of claim 14, wherein the first sensor is oriented to collect data from a location above the first end effector arm link.

17. (canceled)

18. The apparatus of claim 14, further comprising a second sensor, wherein:
the one or more arm links further includes a second end effector arm link having a second end effector,
the second sensor is located within the second end effector arm link,
the one or more arm links further includes a forearm link,
the first end effector arm link is rotatably connected with the forearm link by a first rotational joint of the one or more rotational joints,
the second end effector arm link is rotatably connected with the forearm link by a second rotational joint of the one or more rotational joints, and
the one or more sensor cooling features includes a second sensor cooling feature that is positioned adjacent to or encircling a portion of the second sensor and configured to cool the second sensor when a coolant is flowed into the second sensor cooling feature via at least one of the coolant flow path segments and then out of the second sensor cooling feature via at least one other coolant flow path segment of the coolant flow path segments.

19. The apparatus of claim 18, wherein:
the first rotational joint is configured such that the first end effector arm link is rotatable about a first rotational axis relative to the forearm link,
the second rotational joint is configured such that the second end effector arm link is also rotatable about the first rotational axis relative to the forearm link,
the first end effector is positioned at a higher elevation than the second end effector,
the first end effector link includes a first body portion and a first shaft portion,
the first shaft portion extends through the second end effector link,
the first shaft portion is supported by the first rotational joint,
the first rotational joint includes a first vacuum-compatible seal that seals between the second end effector link and the first portion of the first end effector link,
the second sensor and the second sensor cooling feature are both located within the second arm link at a location that is radially outboard of the first vacuum-compatible seal with respect to the first rotational axis, and
the first vacuum-compatible seal is interposed between the first body portion and a location on the first shaft portion where coolant flow path segments leading to the second sensor cooling feature exit the first portion.

20. The apparatus of claim 19, wherein:
an opening extends through the first shaft portion across a sector of arc about the first rotational axis, and
the coolant flow path segments leading to the second sensor cooling feature exit the first shaft portion via the opening.

21. The apparatus of claim 20, wherein the sector of arc extends through at least 90°.

22. (canceled)

23. The apparatus of claim 1, wherein:
the one or more arm links includes a plurality of arm links;
a second rotational joint rotatably connects two arm links of the plurality of arm links;
at least two of the coolant flow path segments pass through the base rotational joint, and
at least two of the coolant flow path segments pass through the second rotational joint.

24. (canceled)

25. (canceled)

26. The apparatus of claim 1, further comprising a purge gas bleed feature, wherein:
the purge gas bleed feature includes one or more purge gas outlets fluidically connected with one or more purge gas plenums and configured to direct purge gas from the one or more purge gas plenums radially outward in proximity to a corresponding one of the one or more rotational joints, and
one or more purge gas lines are routed from the robot arm base, through the base rotational joint, and into at least the first arm link.

27. (canceled)

28. (canceled)
